(19) United States
(12) Patent Application Publication
(10) Pub. No.: US 2011/0050094 A1
(43) Pub. Date: Mar. 3, 2011

(54) ELECTROLUMINESCENCE SYSTEM WITH TRANSPARENT ELECTRODES

(75) Inventors: Emil Enz, Gais (CH); Adelheid Knechtli-Tschudi, Rheineck (CH)

(73) Assignee: BAYER MATERIALSCIENCE AG, Leverkusen (DE)

(21) Appl. No.: 12/882,286

(22) Filed: Sep. 15, 2010

Related U.S. Application Data
(63) Continuation of application No. 10/578,124, filed on Dec. 5, 2006, now abandoned.

(30) Foreign Application Priority Data
Nov. 3, 2003 (CH) 1890/03

(51) Int. Cl. H01J 1/62

(52) U.S. Cl. 313/506; 313/498

(57) ABSTRACT

The electroluminescent system comprises an electroluminescent device (1) having a first, two-dimensional electrode (2) made of a transparent material. A layer (3,4) made of luminescent dielectric is assigned to each of the large surfaces of said first electrode (2). Said luminescent layers (3,4) are transparent and are made of materials that can emit light with different wavelengths. An electrode (5,6) is assigned to each large surface of the luminescent layers (3, 4) opposite the common electrode (2). A support layer (T) which is also made of transparent material is located on the front side of said electroluminescent device (1). A voltage source (11, 12) is connected between two successive electrodes (5, 2, 6).

The present invention concerns an electroluminescence device.

Known electroluminescence devices of this type have a layer of a luminescent dielectric which is located between two electrodes. The colour of the light emitted by the light layer during operation of such a system is given by the material composition of the light layer. The colour cannot be changed for a given electroluminescence system.

This circumstance restricts the possible applications of the electroluminescence devices.

The object of the present invention is to eliminate this disadvantage and further disadvantages of the known electroluminescence devices.

This object is achieved with the electroluminescence system of the generic type described initially according to the invention as defined in the characterising part of claim 1.

Embodiment examples of the present invention are explained in more detail below with reference to the enclosed drawings. These show:

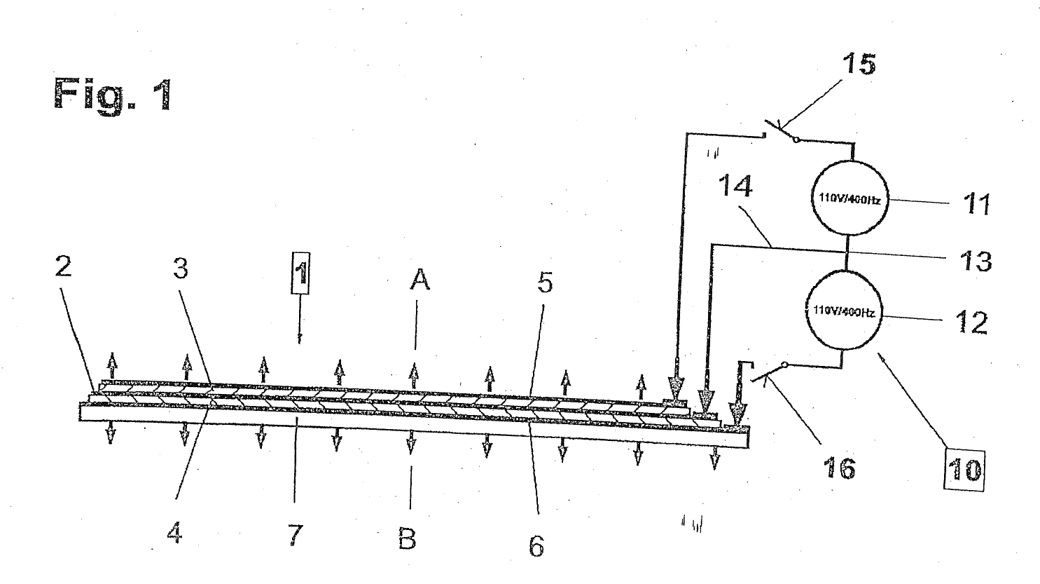

FIG. 1 in a partly vertical section, the structure of a first embodiment of the present invention;

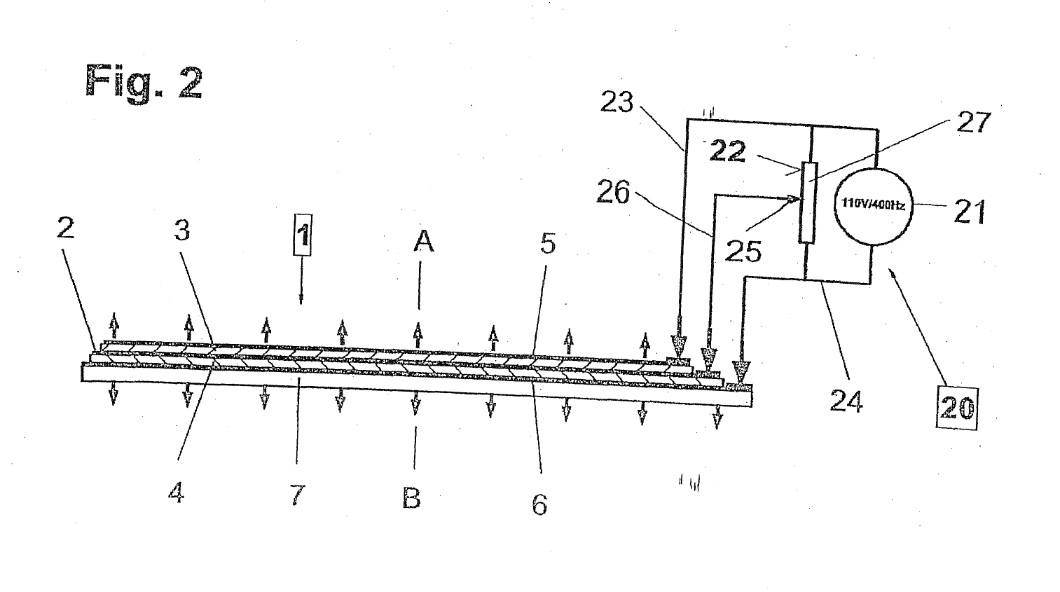

FIG. 2 in a partly vertical section, the structure of a second embodiment of the present invention;

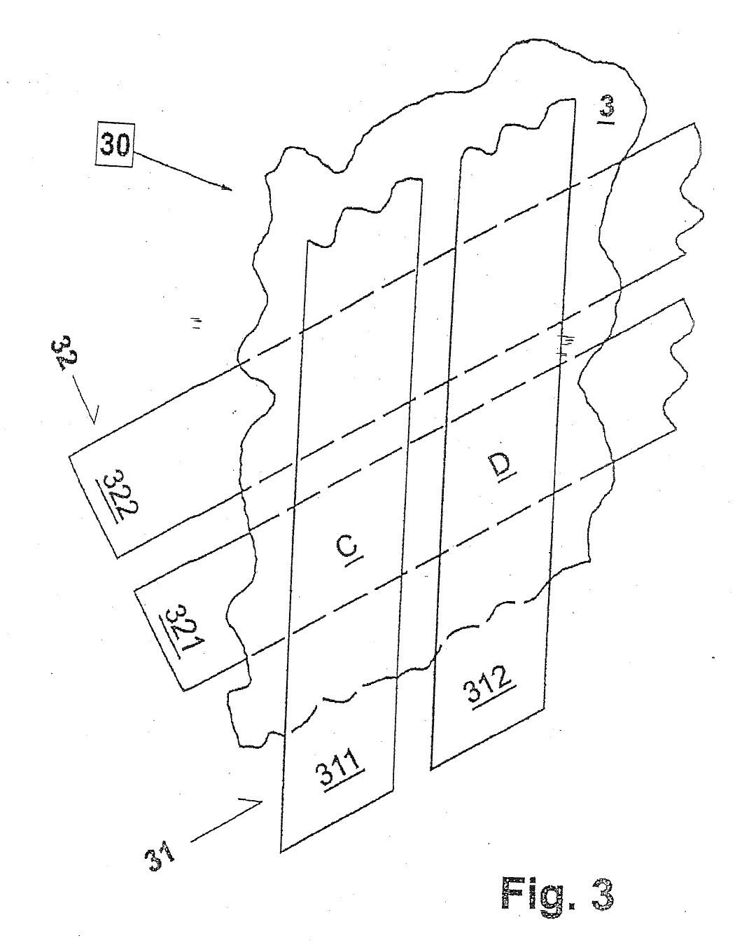

FIG. 3 in perspective and greatly enlarged, the principle of a monochrome screen based on the present invention;

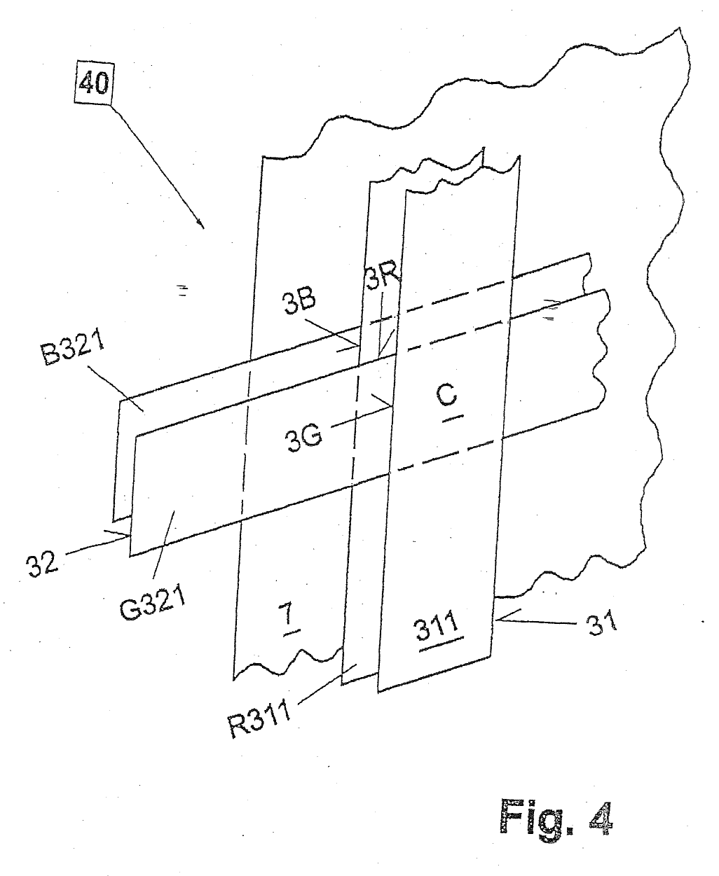

FIG. 4 in perspective and greatly enlarged, the principle of a colour screen based on the present invention; and

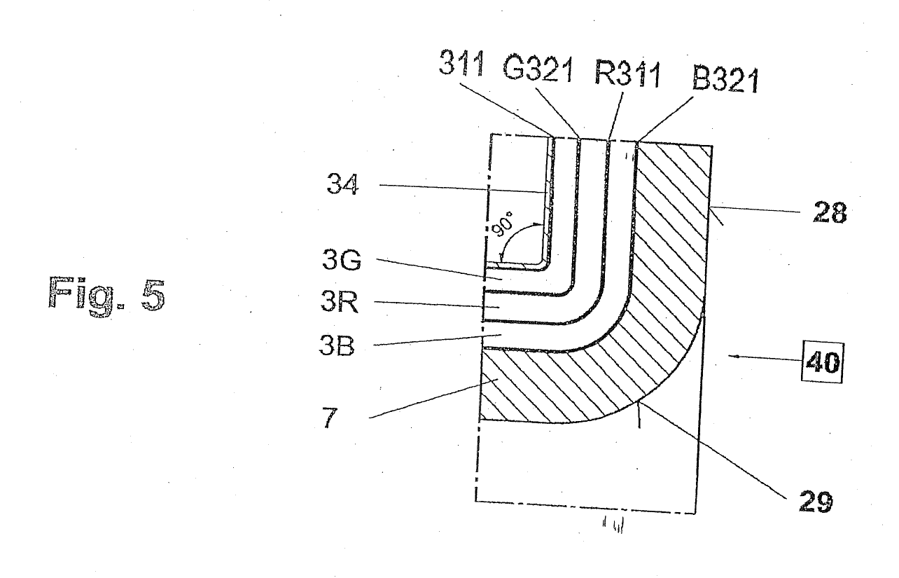

FIG. 5 in a vertical section and greatly enlarged, an extract from the system according to FIG. 4, wherein this FIG. 5 follows the course of the individual layers of the system in FIG. 4 after this device has been deep-drawn.

The present electroluminescence system comprises an electroluminescence device 1 referred to below simply as an EL device. This EL device 1 has a first flat i.e. cohesive electrode 1 of an electrically conductive and also transparent material. Materials of this type are generally known. Each of the large surfaces of this first electrode 2 has a layer 3 or 4 of a luminescent dielectric. These light layers 3 and 4 are designed as cohesive layers. The materials of these light layers are selected so that they can emit light with different wavelengths. Materials of this type are also generally known. Allocated to the large surface of the light layers 3 and 4 facing away from the common electrode 2 is a further electrode 5 and 6. These electrodes 5 and 6 are also transparent.

The material of at least one of the said light layers 3 and 4 is transparent. For example the material of the first light layer 3 could be transparent while the material of the second light layer 4 is opaque. In this case the EL device would emit light only in the direction indicated with the letter A, wherein the electrode 5 attached to the outside of the first light layer 3 as stated above is also transparent. It is however more suitable if the second light layer 4 and the electrode 6 attached to its outer surface are transparent. This EL device 1 emits light only in the direction indicated with the letter B if the first light layer 3 is opaque. There can also be applications in which light is to be emitted from both large surfaces of the EL device 1. For such a case the light layers 3 and 4 and the three electrodes 2, 5 and 6 must be transparent.

Allocated to the large surface of one of the outer electrodes 5 or 6 is a carrier 7 on which is attached the EL device 1. This carrier 7 in most cases is made of a transparent material because in most application cases it constitutes the front of the present EL device. An embodiment of the present device is disclosed below in which the carrier 7 is not transparent and constitutes the back of the EL device 1. The carrier 7 can be rigid or flexible. Also the material of the carrier 7 can be such that this material can be deep-drawn, in particular three-dimensionally. This measure enlarges further the area of application of the present EL device.

The EL layers 3 and 4 can only illuminate when a corresponding electrical voltage is applied to electrodes 2 and 5 or 2 and 6, between which lie the respective EL layers 3 and 4. To this end the present EL device has a supply device 10 designed accordingly which serves as a device to control the luminescent layers 3 and 4 of the electro-luminescence device 1.

The first embodiment of such a supply device 10 shown in FIG. 1 comprises two voltage sources 11 and 12 which are connected in series. At the common point 13 of the series-connected sources 11 and 12 is connected at one end a conductor 14, the other end of which is connected to the first or common electrode 2 of the EL device 1. The other terminal of the first voltage source 11 is connected via a first switch 15 to the second electrode 5 which is on the outside or rear of the first EL layer 3. The other terminal of the second voltage source 12 is connected via a second switch 16 to the third electrode 6 which is on the outside or front of the second EL layer 4. Depending on which of the switches 15 and 16 is conductive, the EL device can emit light with the colour of the first EL layer 3 and with the colour of the second EL layer 4. If both switches 15 and 16 are conductive, then both EL layers 3 and 4 emit light. The result is that the EL device emits light with a colour which arises from the addition or subtraction of the colours of the EL layers 3 and 4.

It should be clear that the electroluminescence device 1 can have more than two transparent and cohesive light layers (not shown) lying above each other. In such a case a broad surface electrode lies between two adjacent light layers in each case. This intermediate electrode or electrodes is/are also transparent. The free surfaces of the outer light layers are also each fitted with an electrode, at least the front electrode 5 being transparent. Between every two electrodes is connected a voltage source as shown in FIG. 1 so that voltage sources form a cascade.

FIG. 2 shows a second embodiment of the said supply device 20. This supply device 20 has only one supply source 21 to which is connected in parallel a potentiometer 22. The first terminal of this supply source 21 and hence also the first terminal of potentiometer 22 is connected via a first conductor 23 to the second or rear electrode 5 of the EL device. The second terminal of the supply source 21 and hence also the second terminal of the potentiometer 22 is connected via a second conductor 24 to the third or rear electrode 5 of the EL device 1. The output point 25 of the potentiometer 2 is connected via a third conductor 26 to the first or common electrode 2 of the EL device. Depending on whether the output 25 is at one end or the other end of the resistance body 27 of the potentiometer 22, the full voltage of the source 21 is applied at the one EL layer 3 or the other EL layer 4. In the position of the output 25 shown in FIG. 2 both EL layers 3 and 4 are under voltage so that the two EL layers 3 and 4 are illuminated. The result is that the EL device 1 emits light with a colour which arises from the addition or subtraction of the colours of the two EL layers 3 and 4.

The fact that the colour of the emitted light can be selected in this way offers the possibility of creating screens to show images. Such screens are suitable in particular for the reproduction of static images. Such screens are also suitable for the reproduction of changing images if the frequency of image change is not high. FIG. 3 shows in perspective the principle of such a device 30 using the example of a black and white screen.

FIG. 3 shows an extract from the flat EL layer 3. The electrode 31 at the front of this device 30 comprises parallel strips 311, 312 of an electrically conductive and transparent material known in itself. In the present case this set of strips 311, 312 etc. runs vertically. The electrode 32 of this device 30 behind the EL layer 3 also comprises parallel strips 321, 322 etc. of an electrically conductive and transparent material known in itself. In the present case this second set of strips 321, 322 etc. runs horizontally. FIG. 3 shows the left lower corner of such a black and white screen 30.

The supply device (not shown) for this EL device 30 is constructed in a known manner so that it can apply an electrical voltage in succession to the individual electrode strips 311, 312 etc. and 321, 322 etc. in a pre-specified manner. At a particular time the voltage is applied to the electrode strips 311 and 312. At this time only that area C of the EL layer 3 which is located between the intersecting electrode strips 311 and 312 is under the effect of the voltage. Consequently only this area C of the EL layer 3 is illuminated at this time. If the supply device 10 applies the voltage at the next time to electrode strips 312 and 321, then only the area D of EL layer 3 illuminates etc. In this way the illuminating points C, D etc. can be moved under control over the entire surface of the EL device.

FIG. 4 shows in greatly simplified form an extract from the left lower corner of a colour screen 40 which has the carrier layer 7. It is suitable if the surface facing the EL device 1 of this carrier 7 is reflective or carries a reflective layer. It is generally known that for example on a screen any colours can be achieved by a combination of the colours yellow, red and blue. The present EL device 40 consequently has three cohesive and transparent layers lying above each other of a electroluminescent dielectric 3G which can illuminate red, an electroluminescent dielectric 3R which can illuminate blue and an electroluminescent dielectric 3B which can illuminate white. In order to keep the diagram in FIG. 4 as clear as possible, layers 3G, 3R and 3B in FIG. 4 are shown only by the reproduction of these references.

The individually pigmented layers 3G, 3R and 3B are controlled in the manner explained in connection with FIG. 3. In contrast, with the EL device 40 according to FIG. 4 however electrode strips lying behind each other are required to control all three luminescent dielectrics 3G, 3R and 3B. These three luminescent dielectrics 3G, 3R and 3B are such that they can emit light of different wavelengths. In FIG. 4 two sets of electrodes are shown which are necessary to control only a single point C of the screen front surface. The description below applies to the other points (pixels) of the screen surface in a similar manner.

From FIG. 3 the first vertical strip 311 of the front electrode 3 has been used for FIG. 4. Behind this vertical strip 311 is an EL layer 3G. Behind this EL layer 3G is the first horizontal strip G321 and consequently the prefix G is applied to the number of this horizontal strip G321. To control pixel C so that this lights, the necessary voltage is connected to strips 311 and G321.

Behind the horizontal strip G321 is the EL layer 3R which like EL layer 3G is flat and which also has allocated to it several electrode strips both vertical and horizontal. Behind the EL layer 3R is a vertical strip R311 and consequently prefix R is given to the number of the horizontal strip R311. So that pixel C here lights up, the control voltage is connected to the electrode strips G321 and R311. The horizontal strip G321 thus serves not only to control the EL layer 3G but also to control the EL layer 3R in the same way as described in connection with the common electrode 2 in FIG. 1.

Behind the vertical strip R311 is the flat EL layer 3B and behind this EL layer 3B is arranged the horizontal strip B321. So that pixel C here lights up, the control voltage is connected at the electrode strips B321 and R311. The vertical strip R311 serves not only to control the EL layer 3R but also to control the EL layer 3B in the same way as described in connection with the common electrode 2 in FIG. 1. The horizontal strip B321 however serves only as the rear electrode 6 in FIG. 1. If pixel C is to show a colour which arises from a combination of the said base colours, then corresponding voltages are applied to the electrode strips concerned in a known manner. The control with the strip-like intersecting electrodes can also be called a matrix control. It is however possible to control the transparent light layers 3G, 3R and 3B by pixels. Such pixel controls are also known per se.

Also the present system can be designed so that not only can it bend but it can also be formed three-dimensionally, e.g. stretched or even deep-drawn. FIG. 5 shows an extract from a deep-drawn point of the EL device 40 which arises from the depiction in FIG. 4. The extract shown in FIG. 5 from the deep-drawn point of the flat screen 40 comprises two sections 28 and 29 which between them enclose an angle of 90°. This extremely great flexibility of EL device 40, where the bending radius can be in the area of even less than 1 mm, is possible because the material of light layers 3G, 3R and 3B is very flexible and the individual layers, i.e. both the electrodes and the light layers of the screen, adhere to each other unshiftingly during the bending process. This technology is described in detail in a patent application WO 03/037039 by the same holder. In addition to the depiction in FIG. 4, screen 40 according to FIG. 5 has a cover layer 34 which is applied to the outer electrode 311.

Screens of the type described here have the advantages that they are not sensitive to contact, that they bend and can even be deep-drawn and that they can be produced in conventional printing processes, e.g. in screen printing.

What is claimed:

1. An electroluminescence system comprising an electroluminescence device which is activatable by alternating current and has a first flat electrode of a transparent material, whereby to each of the large surfaces of this first electrode a layer of a luminescent dielectric is allocated and a second electrode is allocated to the large surface of the luminescent layer concerned facing away from the common electrode, wherein both the electrodes and the luminescent layers are transparent.

2. A system according to claim 1, wherein the electroluminescence device has more than two transparent luminescent layers lying above each other, whereby between every two luminescent layers is arranged a transparent electrode and the free large surfaces of the outside luminescent layers are also fitted with an electrode.

3. A system according to claim 2, wherein the electroluminescence device has three transparent luminescent layers above each other.

4. A system according to claim 1, wherein the luminescent layers are made of materials which can emit light at different wavelengths.

5. A system according to claim 1, wherein the extensive electroluminescence device has at least one point with a three-dimensional deformation, that this deformation has a radius which is less than 1 mm, wherein the deformed points are connected by at least two sections of the electroluminescence device, between which extends an angle which can amount to 90°.

6. A system according to claim 1, including a device to control the luminescent layers of the electroluminescence device.

7. An electroluminescence system comprising an electroluminescence device which is activatable by alternating current and having at least one layer of a luminescent dielectric, whereby an electrode is allocated to each of the large surfaces of this luminescent layer, wherein the electrode concerned is designed as a set of parallel strips of an electrically conductive material, such that the directions of these sets of strips are perpendicular to each other, and a control device is provided which is designed so that the electrode strips can be connected individually to an energy source.

8. A system according to claim 7, wherein the luminescent layer is designed as a cohesive layer.

9. A system according to claim 7, wherein the electroluminescence device has several transparent layers of luminescent dielectric lying above each other, that the luminescence dielectrics of the luminescent layers are such that they can emit light of different wavelengths, such that between every two such luminescent layers is arranged a strip electrode and that the free surfaces of the outside luminescent layers each have a strip electrode.

10. A system according to claim 7, wherein a reflective layer is allocated to the rear of the electroluminescence device such that the reflected surface of this layer faces the luminescent layers of the electroluninescence device.
